(19) United States
(12) Patent Application Publication
(10) Pub. No.: US 2026/0362935 A1
(43) Pub. Date: Nov. 12, 2026

(54) DISPLAY DEVICE, MANUFACTURING METHOD OF DISPLAY DEVICE AND ELECTRONIC DEVICE INCLUDING DISPLAY DEVICE

(71) Applicant: Samsung Display Co., Ltd., Yongin-si (KR)

(72) Inventors: Su Jung HUH, Yongin-si (KR); Koichi ABE, Yongin-si (KR); Dae Young LEE, Yongin-si (KR); Won Ju KIM, Yongin-si (KR)

(21) Appl. No.: 19/411,666

(22) Filed: Dec. 8, 2025

(30) Foreign Application Priority Data
May 9, 2025 (KR) 10-2025-0060564

(51) Int. Cl. H10K 59/50; G02F 1/137; H10K 50/19; H10K 59/12; H10K 59/122; H10K 59/80

(52) U.S. Cl. CPC H10K 59/50; G02F 1/13718; H10K 50/19; H10K 59/1201; H10K 59/122; H10K 59/8793

(57) ABSTRACT

A display device, a method for manufacturing the display device, and an electronic device including the display device may be provided. The display device may include light-emitting elements that may emit light of different colors and including a first light-emitting element having a tandem structure and a second light-emitting element comprising a second emission layer, where the tandem structure may include a plurality of first emission layers that may be stacked, a first light controller above the first light-emitting element and including a first phase difference layer and a polarizing plate above the first phase difference layer, and a second light controller above the second light-emitting element and including a first coloring layer.

### CROSS-REFERENCE TO RELATED APPLICATION

The present application claims priority to and the benefit of Korean Patent Application No. 10-2025-0060564, filed on May 9, 2025, in the Korean Intellectual Property Office, the entire disclosure of which is incorporated herein by reference.

### BACKGROUND

### 1. Field

Embodiments of the present disclosure may relate to a display device, a manufacturing method of the display device, and an electronic device including the display device. For example, the present disclosure may relate to a display device including a light-emitting element and a light controller, a manufacturing method of the display device, and an electronic device including the display device.

### 2. Description of the Related Art

In a display device such as an organic light-emitting diode (OLED) display device and a liquid crystal display (LCD), a display substrate including, for example, a thin film transistor (TFT) and one or more suitable lines may be provided. A display structure including electrodes and an emission layer may be formed on the display substrate.

For example, the OLED display device may include a light-emitting element including an organic emission layer. In addition, a color filter may be added to improve image characteristics or color characteristics generated from the light-emitting element.

### SUMMARY

One or more aspects of embodiments of the present disclosure may provide a display device with improved optical characteristics.

One or more aspects of embodiments of the present disclosure may also provide a method for manufacturing a display device with improved optical characteristics.

One or more aspects of embodiments of the present disclosure may also provide an electronic device including a display device with improved optical characteristics.

According to one or more aspects of embodiments of the present disclosure, a display device may include light-emitting elements that may emit light of different colors and including a first light-emitting element having a tandem structure and a second light-emitting element including a second emission layer, where the tandem structure of the first light-emitting element may include a plurality of first emission layers that may be stacked, a first light controller above (e.g., disposed on) the first light-emitting element and including a first phase difference layer and a polarizing plate above the first phase difference layer, and a second light controller above the second light-emitting element and including a first coloring layer.

In one or more embodiments, the first phase difference layer may be a cholesteric liquid crystal layer of an emission color of the first light-emitting element.

In one or more embodiments, the polarizing plate may include a linear polarizing plate above a quarter wave plate.

In one or more embodiments, the first light-emitting element may be a blue light-emitting element.

In one or more embodiments, an aperture ratio of the first light-emitting element may be greater than an aperture ratio of the second light-emitting element.

In one or more embodiments, the display device may have a b* value of -1.0 or more in Lab color coordinates.

In one or more embodiments, the display device may further include a third light-emitting element emitting light of a different color from the first and second light-emitting elements and having a tandem structure, where the tandem structure of the third light-emitting element may include third emission layers, and a third light controller above the third light-emitting element and including a second phase difference layer and the polarizing plate.

In one or more embodiments, a number of third emission layers may be the same as a number of first emission layers.

In one or more embodiments, the second phase difference layer may be a cholesteric liquid crystal layer of an emission color of the third light-emitting element.

In one or more embodiments, the first light-emitting element may be a blue light-emitting element, and the third light-emitting element may be a green light-emitting element.

In one or more embodiments, the display device may further include a third light-emitting element emitting light of a different color from the first and second light-emitting elements and including one third emission layer, and a third light controller above the third light-emitting element and including a second coloring layer.

In one or more embodiments, the first light-emitting element may include emission structures, where respective emission structures may include a corresponding first emission layer, and the emission structures may be stacked with a charge generation layer, and where the charge generation layer may be between (e.g., disposed between) the emission structures.

According to one or more aspects of embodiments of the present disclosure, a method may include forming a first light emitter including a plurality of first emission layers, forming a second light emitter including one second emission layer, forming (e.g., disposing) a first light controller on (e.g., above) the first light emitter, the first light controller including a first phase difference layer and a polarizing plate above the first phase difference layer, and forming a second light controller on the second light emitter, the second light controller including a first coloring layer, where the method may be a method for manufacturing a display device.

In one or more embodiments, the first light emitter may be formed on a first pixel electrode, and the second light emitter may be formed on a second pixel electrode.

In one or more embodiments, the method may further include forming an electrode on the first light emitter and the second light emitter, and forming a bank on the electrode, the bank defining a first opening on the first light emitter and a second opening on the second light emitter.

In one or more embodiments, the first light controller may be formed at the first opening, and the second light controller may be formed at the second opening.

In one or more embodiments, a size of the first opening may be greater than a size of the second opening.

In one or more embodiments, the method may further include forming a third light emitter including third emission layers, and forming a third phase difference layer on the third light emitter, and where the forming of the first light controller may include forming the first phase difference layer on the first light emitter, and forming the polarizing plate covering the first phase difference layer and the third phase difference layer.

According to one or more aspects of embodiments of the present disclosure, an electronic device may include a display device, a memory, and a processor controlling an operation of the display device by executing data stored in the memory, where the display device may include light-emitting elements that may emit light of different colors and including a first light-emitting element having a tandem structure and a second light-emitting element comprising one second emission layer, where the tandem structure may include a plurality of first emission layers that may be stacked, a first light controller above the first light-emitting element and including a first phase difference layer and a polarizing plate above the first phase difference layer, and a second light controller above the second light-emitting element and including a first coloring layer.

In one or more embodiments, the electronic device may include virtual reality (VR) or augmented reality (AR) glasses, a smartphone, a tablet personal computer (PC), a laptop computer, a television (TV), a monitor for a desktop computer, smart glasses, a head mounted display, a smart watch, and/or a vehicle display.

According to one or more embodiments of the present disclosure, at least some of light-emitting elements may have a tandem structure (e.g., a light-emitting element may include a light emitter disposed between layers of the tandem structure), and furthermore, a phase difference layer and a polarizing plate may be above the light-emitting elements having the tandem structure. Accordingly, optical/color characteristics may be effectively implemented, and a lifespan of the light-emitting elements having the tandem structure may be improved.

### BRIEF DESCRIPTION OF THE DRAWINGS

The above and other aspects and features of embodiments of the present disclosure will become more apparent by describing in more detail embodiments thereof with reference to the attached drawings, in which:

FIG. 1 is a schematic plan view of a display device according to one or more embodiments;

FIG. 2 is a schematic plan view illustrating a light controller of the display device according to one or more embodiments;

FIG. 3 is a schematic cross-sectional view of the display device according to one or more embodiments;

FIG. 4 is a schematic cross-sectional view illustrating a light-emitting element of the display device according to one or more embodiments;

FIG. 5 is a schematic cross-sectional view of the display device according to one or more embodiments;

FIGS. 6A-6C are views for describing external light reflectivities according to one or more embodiments;

FIG. 7 is a diagram for describing an aspect of color sense adjustment according to one or more embodiments;

FIG. 8 is a comparison table for describing an aspect according to one or more embodiments;

FIGS. 9A-9E are cross-sectional views illustrating a manufacturing method of the display device according to one or more embodiments;

FIGS. 10A, 10B, and 11A-11C are schematic cross-sectional views of display devices according to one or more embodiments;

FIG. 12 is an exploded perspective view illustrating an electronic device according to one or more embodiments;

FIG. 13 is a block diagram of an electronic device according to one or more embodiments; and

FIG. 14 is schematic views of electronic devices according to one or more embodiments.

### DETAILED DESCRIPTION

The subject matter of the present disclosure will now be described hereinafter with reference to the accompanying drawings, in which one or more embodiments of the present disclosure may be shown. The subject matter of the present disclosure may, however, be embodied in different forms and may not be construed as limited to one or more embodiments set forth herein. Rather, these embodiments are provided so that this disclosure will be thorough and complete, and will fully convey the scope of the present disclosure to those skilled in the art.

It will also be understood that when a layer is referred to as being “on,” “connected to”, “coupled to”, or “adjacent to” another layer or substrate, it may be directly on, connected to, coupled to, or adjacent to the other layer or substrate, or intervening layers may also be present. In contrast, when an element or layer is referred to as being “directly on,” “directly connected to”, “directly coupled to”, or “immediately adjacent to” another element or layer, there are no intervening elements or layers present. The same reference numbers may indicate the same components throughout the present specification.

It will be understood that, although the terms “first,” “second,” etc. may be utilized herein to describe suitable elements, these elements may not be limited by these terms. These terms are only utilized to distinguish one element from another element. For instance, a first element discussed below could be termed a second element without departing from the teachings of the present disclosure. Similarly, the second element could also be termed the first element.

In the present disclosure, “A and/or B” may refer to A or B, or A and B. In the present disclosure, “at least one of A and B” may refer to A or B, or A and B.

It will be understood that if (e.g., when) a layer, region, or component is referred to as being "connected" to another layer, region, or component, it may be "directly connected" to the other layer, region, or component or may be "indirectly connected" to the other layer, region, or component with other layer, region, or component interposed therebetween. For example, it will be understood that if (e.g., when) a layer, region, or element is referred to as being "electrically connected" to another layer, region, or element, it may be "directly electrically connected" to the other layer, region, or element or may be "indirectly electrically connected" to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different directions that are not normal (e.g., perpendicular) to one another.

One or more aspects of the suitable embodiments of the present disclosure may be combined or combined with each other, in part or in whole, and technically suitable interlocking and driving are possible. Each embodiment may be implemented independently of each other or may be implemented together in an association.

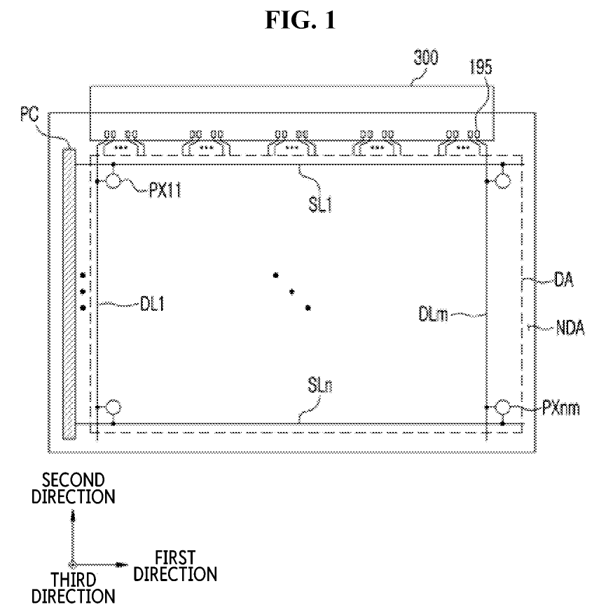

FIG. 1 is a schematic plan view of a display device according to one or more embodiments. For example, FIG. 1 is a plan view illustrating a pixel arrangement of the display device according to one or more embodiments.

In FIG. 1, a first direction and a second direction may refer to two directions parallel to a display surface of the display device and perpendicular to each other. For example, the first direction may correspond to an X-axis direction (e.g., a row direction), and the second direction may correspond to a Y-axis direction (e.g., a column direction) of the display device. A third direction may be perpendicular to the first direction and the second direction. The third direction may correspond to a Z-axis direction (e.g., a thickness direction) of the display device.

The definitions of the directions described above may be equally applied to the other drawings.

Referring to FIG. 1, a plurality of pixels PX11 to PXnm may be arranged in a display area DA of the display device.

According to one or more embodiments, a pixel circuit including scan lines (or gate lines) SL1 to SLn forming first to n-th rows and data lines DL1 to DLm forming first to m-th columns may be arranged on a base substrate 100 of the display device. Each of the pixels PX11 to PXnm may be coupled to (e.g., connected to) a scan line of a corresponding n-th row among the plurality of scan lines SL1 to SLn and a data line of a corresponding m-th column among the plurality of data lines DL1 to DLm.

Each of the pixels PX11 to PXnm may further include a pixel circuit including a transistor and a light-emitting element, as described herein. In one or more embodiments, the pixel circuit may further include lines such as a power line and/or a ground line.

It may be illustrated in FIG. 1 that the data lines DL1 to DLm may be to extend in the second direction and the scan lines SL1 to SLn may be to extend in the first direction, but the present disclosure may be not necessarily limited thereto.

A peripheral circuit PC may be at (e.g., disposed in) a non-display area NDA corresponding to a peripheral area of the display area DA. For example, the peripheral circuit PC may include a gate driving circuit. The gate driving circuit may be integrated in the display device through an oxide silicon gate driver circuit (OSG), amorphous silicon gate driver circuit (ASG), and/or polysilicon gate driver circuit (PSG) process.

The peripheral circuit PC may further include a data driver, a gate driver, an emission driver, a source voltage generator, a timing controller, and/or the like.

The display device may further include a printed circuit board 300. Pad portions 195 of the pixel circuit may be bonded to one side portion of the non-display area NDA. The printed circuit board 300 may be electrically connected to the pixel circuit through the pad portions 195. For example, the printed circuit board 300 may be electrically connected to the pad portions 195 through a heating-compression process utilizing a conductive intermediary structure such as an anisotropic conductive film (ACF).

An integrated circuit (IC) such as a data driving circuit may be above (e.g., disposed on) the printed circuit board 300. In one or more embodiments, an integrated circuit (IC) chip may be mounted in a chip-on-film (COF) form on the printed circuit board 300.

Hereinafter, configurations/structures of the display device according to the present disclosure will be described utilizing an organic light-emitting display device as an example However, the display device disclosed herein may also be applied to suitable types of display devices such as an inorganic light-emitting display device and a quantum dot light-emitting display device.

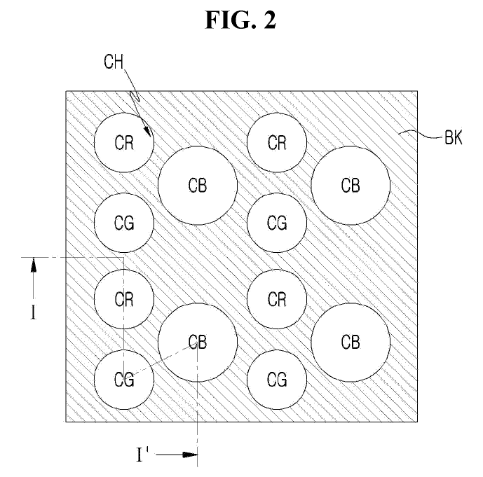

FIG. 2 is a schematic plan view illustrating a light controller of the display device according to one or more embodiments.

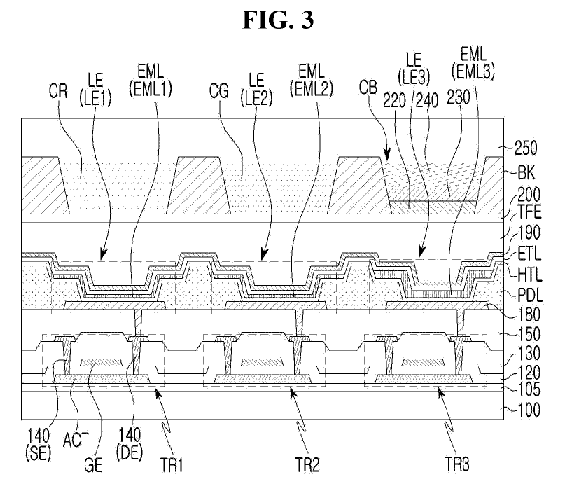

Referring to FIG. 2, for example, a light controller (e.g., a light control unit) and a bank BK dividing/defining the light controller may be disposed on an encapsulation layer TFE (see FIG. 3) of the display device.

For example, the bank BK may include a polymer resin material and/or a photoresist material having light blocking properties, and may be provided (e.g., formed) through a photolithography process including exposure and development processes.

The bank BK may include openings CH formed through the photolithography process. The light controller may be at (e.g., disposed in) each of the openings CH.

The light controller may include first light controllers CR, second light controllers CG, and third light controllers CB. According to one or more embodiments, at least some of the light controllers may be provided as a stacked structure including a phase difference layer and a polarizing plate, and the others of the light controllers (e.g., the remaining light controllers) may be provided as coloring layers of color filters.

The phase difference layer may be configured as a cholesteric liquid crystal (CLC) layer. A CLC may form a layered structure like a smectic liquid crystal, but molecules of a major axis may have a parallel arrangement similar to a nematic liquid crystal within a plane. The CLC may have a structure in which thin and long molecules may be evenly arranged in a major-axis direction within one plane and arrangement orientations of molecular axes slightly deviated toward a direction perpendicular to the plane, and may have a structure in which an arrangement direction of the molecules may turn in a helical shape. Accordingly, the entire liquid crystal may have a helical structure.

The CLC layer may be to selectively transmit or reflect circularly polarized light. The CLC layer may have a property of reflecting circularly polarized light in substantially the same direction as a helical direction in which light may be incident and transmitting circularly polarized light in an opposite direction to the helical direction. Accordingly, the CLC layer may be to selectively reflect/transmit right-handed or left-handed circularly polarized light.

The polarizing plate may be a circular polarizing plate. The polarizing plate may include a quarter wave plate (QWP) and a linear polarizing plate disposed on the quarter wave plate.

The quarter wave plate may generate a phase retardation of λ/4.

The linear polarizing plate may have a polarization axis, and may linearly polarize light in a polarization axis direction. The linear polarizing plate may be to transmit light that may coincide with the polarization axis and absorb light that may not coincide with the polarization axis. Accordingly, if (e.g., when) light passes through the linear polarizing plate, the light may be linearly polarized in the polarization axis direction.

The quarter wave plate may have an optical axis approximately deviating from the polarization axis of the linear polarizer by 45°. According to such a disposition, external light may be reflected by the light-emitting element, and the reflected light may become perpendicular to a transmission axis of the linear polarizing plate when it may be emitted to the outside, such that a reflectivity may be reduced.

According to one or more embodiments, the light controller may have a structure in which the CLC layer, the quarter wave plate, and the linear polarizing plate may be stacked, such that the reflected light may be recycled to improve luminance. The light reflected by the CLC layer may be recycled to improve luminance, and the light transmitted through the CLC layer may coincide with the transmission axis of the linear polarizing plate utilizing the quarter wave plate to further improve transmissivity.

The coloring layer may be formed utilizing a coloring resin composition including a binder resin and a coloring agent (e.g., a dye and/or a pigment). According to one or more embodiments, the coloring layer may be formed by filling the opening CH with the coloring resin composition through a printing process such as an inkjet process.

In one or more embodiments, the third light controller CB may be provided as the phase difference layer and the polarizing plate, and the first light controller CR and the second light controller CG may be provided as a red coloring layer and a green coloring layer, respectively.

As illustrated in FIG. 2, for example, the first light controllers CR and the second light controllers CG may be alternately and repeatedly arranged along the second direction. The third light controller CB may have a greater area than the first light controller CR and the second light controller CG. The third light controller CB may be adjacent to the first light controller CR or the second light controller CG in the first direction.

For example, the first light controllers CR and the second light controllers CG may be alternately and repeatedly arranged to form a light control column. The light control columns may be repeatedly arranged along the first direction. The third light controllers CB may be repeatedly arranged between the light control columns neighboring to each other along the second direction.

In one or more embodiments, a light control group may be defined by one first light controller CR and one second light controller CG neighboring to each other in the second direction and one third light controller CB adjacent to the one first light controller CR and the one second light controller CG. The light control groups may be repeatedly arranged along the first direction and the second direction.

An arrangement of the light controllers described with reference to FIG. 2 may be provided by way of example, and a structure of the light controller included in the display device according to the present disclosure may be not limited to a structure illustrated in FIG. 2.

FIG. 3 is a schematic cross-sectional view of the display device according to one or more embodiments. For example, FIG. 3 is a cross-sectional view taken along the line I-I’ of FIG. 2 in the thickness direction (e.g., the third direction).

Referring to FIG. 3, the display device may include a base substrate 100, a pixel circuit, and a light-emitting element LE.

The base substrate 100 may be provided as a backplane substrate of the display device. A glass substrate or a plastic substrate may be utilized as the base substrate 100. In one or more embodiments, the base substrate 100 may include a polymer material having transparency and selected flexibility. For example, the base substrate 100 may be utilized in a transparent flexible display device.

For example, the base substrate 100 may include a polymer material such as polyimide, polysiloxane, an epoxy resin, an acrylic resin, and/or polyester. In one or more embodiments, the base substrate 100 may include polyimide.

A buffer layer 105 may be formed on an upper surface of the base substrate 100. Moisture permeating through the base substrate 100 may be blocked or reduced by the buffer layer 105, and diffusion of impurities between the base substrate 100 and a structure formed on the base substrate 100 may be blocked or reduced by the buffer layer 105. In one or more embodiments, the buffer layer 105 may be entirely formed over the display area DA and the non-display area NDA of the base substrate 100, and may entirely cover the upper surface of the base substrate 100.

The buffer layer 105 may include, for example, an inorganic insulating material such as silicon oxide, silicon nitride, and/or silicon oxynitride. These materials may be utilized alone or in a combination of two or more. In one or more embodiments, the buffer layer 105 may have a stacked structure including a silicon oxide film and a silicon nitride film. For example, the stacked structure may be provided by stacking at least one silicon oxide film and at least one silicon nitride film. The buffer layer 105 may be formed through a deposition process, such as a chemical vapor deposition (CVD) process, a sputtering process, and/or an atomic layer deposition (ALD) process, to include the above-described inorganic insulating material.

In one or more embodiments, the buffer layer 105 may include an organic layer or may have a multilayer structure of an organic layer and an inorganic layer. For example, the multilayer structure may include at least one organic layer and at least one inorganic layer.

The pixel circuit may include lines including the scan lines and the data lines described with reference to FIG. 1 and transistors TR1, TR2, and TR3 electrically interacting with the lines. The transistors TR1, TR2, and TR3 may be electrically connected to light-emitting elements LE1, LE2, and LE3.

Each of the transistors TR1, TR2, and TR3 may include an active layer ACT, a gate-insulating layer 120, and a gate electrode GE.

The active layer ACT may be disposed on the buffer layer 105, and may be patterned through, for example, a photolithography process to be repeatedly/regularly arranged for each pixel. The active layer ACT may include a silicon compound such as polysilicon and/or amorphous silicon. At least some regions of the active layer ACT may be doped with a p-type (kind) dopant or an n-type (kind) dopant, and may include a source region, a drain region, and/or a channel region.

The active layer ACT may include an oxide semiconductor such as indium gallium zinc oxide (e.g., IGZO), zinc tin oxide (e.g., ZTO), and/or indium tin zinc oxide (e.g., ITZO).

The gate-insulating layer 120 may be formed on the active layer ACT, and the gate electrode GE may be stacked on the gate-insulating layer 120. As illustrated in FIG. 3, the gate-insulating layer 120 may be continuously and commonly provided for a plurality of transistors TR1, TR2, and TR3 or pixels of different colors. Alternatively, the gate-insulating layer 120 may be formed in a pattern shape partially covering each active layer ACT.

The gate electrode GE may overlap the channel region of the active layer ACT in the third direction. A scan signal may be transmitted from the scan line through the gate electrode GE.

The gate-insulating layer 120 may be formed through the above-described deposition process to include an inorganic insulating material such as silicon oxide, silicon nitride, and/or silicon oxynitride.

In one or more embodiments, the source region and the drain region may be formed in the active layer ACT utilizing the gate electrode GE as an ion implantation mask.

An interlayer-insulating layer 130 covering the gate-insulating layer 120 and the gate electrode GE may be formed on the active layer ACT. A connection electrode 140 in contact with or electrically connected to the active layer ACT may be formed on the interlayer-insulating layer 130.

The interlayer-insulating layer 130 may be formed through the above-described deposition process to include an inorganic insulating material such as silicon oxide, silicon nitride, and/or silicon oxynitride. The interlayer-insulating layer 130 may be formed in a single-layer structure or a multilayer structure including different materials.

In one or more embodiments, in a case where the gate-insulating layer 120 may have an individual pattern shape and the active layer ACT may include the oxide semiconductor, when the interlayer-insulating layer 130 may be formed, hydrogen (H) included in the interlayer-insulating layer 130 may be diffused or moved to the active layer ACT. Accordingly, a carrier concentration may be increased by hydrogen, such that the source region and the drain region may be formed on side portions of the active layer ACT.

The connection electrode 140 may be to penetrate through the interlayer-insulating layer 130 and be connected to the active layer ACT. The connection electrode 140 may be also to penetrate through the gate-insulating layer 120.

The connection electrode 140 may include a source electrode SE connected to or in contact with the source region of the active layer ACT and a drain electrode DE connected to or in contact with the drain region of the active layer ACT.

Contact holes may be formed by partially etching the interlayer-insulating layer 130. For example, contact holes respectively exposing the source region and the drain region may be formed. The contact holes may be to penetrate through the gate-insulating layer 120 together.

The source electrode SE and the drain electrode DE may be formed by forming a metal layer sufficiently filling the contact holes on the interlayer-insulating layer 130 and then partially etching the metal layer. For example, a data signal may be transmitted from the data line through the source electrode SE.

The gate electrode GE and the connection electrode 140 may include a metal such as Ag, Mg, Al, W, Cu, Ni, Cr, Mo, Ti, Pt, Ta, Nd, Sc, alloys thereof, and/or nitride thereof. The gate electrode GE and the connection electrode 140 may be formed through the above-described deposition process such as the sputtering process. The gate electrode GE and/or the connection electrode 140 may have a multilayer structure including different metal layers.

A planarization layer 150 covering the connection electrodes 140 may be formed on the interlayer-insulating layer 130. The planarization layer 150 may accommodate a via portion electrically connecting a pixel electrode 180 and the drain electrode DE to each other.

In one or more embodiments, the planarization layer 150 may include an organic material such as polyimide, an epoxy resin, an acrylic resin, polyester, a siloxane resin, and/or benzocyclobutene (BCB). The planarization layer 150 may be formed through a coating process such as a spin coating process and/or the above-described deposition process.

The pixel electrode 180 may be formed for each pixel and electrically connected to the transistor. The pixel electrode 180 may be formed on the planarization layer 150 and electrically connected to the drain electrode DE.

For example, a via hole exposing an upper surface of the drain electrode DE may be formed by partially etching the planarization layer 150. The pixel electrode 180 may be formed by forming a conductive layer sufficiently filling the via hole and including a metal material or transparent conductive oxide on an upper surface of the planarization layer 150 and then etching the conductive layer. The pixel electrode 180 may include the via portion filling the via hole.

The pixel electrode 180 may be provided as an anode, and may include a high work function conductive material promoting injection of holes. The pixel electrode 180 may be provided as a transmissive electrode. The pixel electrode 180 may include a transparent conductive oxide, such as indium tin oxide (e.g., ITO), indium zinc oxide (e.g., IZO), zinc oxide (e.g., ZnO), and/or indium tin zinc oxide (e.g., ITZO).

The pixel electrode 180 may be provided as a semi-transmissive electrode and/or a reflective electrode. The pixel electrode 180 may include a metal selected from among the group including (e.g., consisting of) Ag, Mg, Cu, Al, Pt, Pd, Au, Ni, Nd, Ir, Cr, Li, Ca, LiF, Mo, Ti, W, In, Sn, and Zn, and/or alloys of two or more thereof.

The pixel electrode 180 may have a single-layer structure and/or a multilayer structure. For example, the pixel electrode 180 may have a three-layer structure such as ITO/Ag/ITO (e.g., a layer of ITO, a layer of Ag, and a layer of ITO) or ITO/Al/ITO (e.g., a layer of ITO, a layer of Al, and a layer of ITO).

A pixel defining layer PDL exposing an upper surface of the pixel electrode 180 may be formed on the planarization layer 150. The pixel defining layer PDL may be formed, such that an opening at least partially exposing the upper surface of the pixel electrode 180 may be formed, and a pixel area may be defined by the opening. The pixel defining layer PDL may cover a peripheral portion of the pixel electrode 180.

For example, the pixel area or an emission area may be defined by a sidewall of the pixel defining layer PDL. A first pixel including a first transistor TR1 and a first light-emitting element LE1, a second pixel including a second transistor TR2 and a second light-emitting element LE2, and a third pixel including a third transistor TR3 and a third light-emitting element LE3 may be separated or apart from each other and defined by the pixel defining layer PDL.

In one or more embodiments, the first pixel, the second pixel, and the third pixel may correspond to a red pixel, a green pixel, and a blue pixel, respectively.

The pixel defining layer PDL may include an organic material such as a polysiloxane resin, a polyimide resin, and/or an acrylic resin. The pixel defining layer PDL may also include a colorant such as a black pigment/dye dispersed in the resin material. The pixel defining layer PDL may also include an inorganic layer such as a silicon oxide film and/or a silicon nitride film.

In one or more embodiments, the pixel defining layer PDL may have a step structure (e.g., a shape or structure that may be like steps or stairs) as illustrated in FIG. 3.

An emission layer EML may be disposed on an exposed surface of the pixel electrode 180. In one or more embodiments, the emission layer EML may include an organic emission material independently patterned for each of the red pixel, the green pixel, and the blue pixel to emit light of different colors for each pixel.

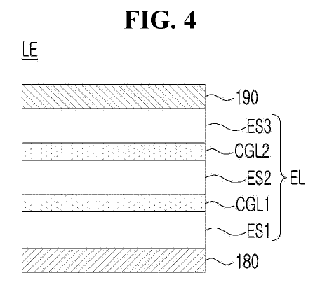

The emission layer EML may include a first emission layer EML1 included in the first pixel and including a red organic light-emitting material, a second emission layer EML2 included in the second pixel and including a green organic light-emitting material, and a third emission layer EML3 included in the third pixel and including a blue organic light-emitting material. The third emission layer EML3 may have a structure in which a plurality of emission layers are stacked, as described herein with reference to FIG. 4.

For example, the organic light-emitting material may include a host material excited by holes and electrons and a dopant material increasing luminous efficiency through absorption and emission of energy.

In one or more embodiments, a hole transporting layer HTL may be disposed between the pixel electrode 180 and the emission layer EML. An electron transporting layer ETL may be disposed on the emission layer EML.

The hole transporting layer HTL and electron transporting layer ETL may be to extend commonly and continuously across a plurality of light-emitting elements LE and pixels.

For example, the hole transporting layer HTL may include a hole transporting material such as 4,4’,4”-[tris(3-methylphenyl)phenylamino] triphenylamine (m-MTDATA), 4,4’4”-tris(N,N-diphenylamino)triphenylamine (TDATA), 4,4’,4”-tris[N(2-naphthyl)-N-phenylamino]-triphenylamine (2-TNATA), N,N’-di(naphthalene-l-yl)-N,N’-diphenyl-benzidine (NPB), N,N’-bis(3-methylphenyl)-N,N’-diphenyl-[1,1’-biphenyl]-4,4’-diamine (TPD), 4,4’,4”-tris(N-carbazolyl)triphenylamine (TCTA), and/or poly(3,4-ethylenedioxythiophene)/poly(4-styrenesulfonate) (PEDOT/PSS).

For example, the electron transporting layer ETL may include an electron transporting material such as an anthracene compound, tris(8-hydroxyquinolinato)aluminum (Alq₃), 1,3,5-Tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), and/or bis(2-methyl-8-quinolinolato-N1,O8)-(1,1’-biphenyl-4-olato)aluminum (BAlq).

Each of the emission layer EML, the hole transporting layer HTL, and/or the electron transporting layer ETL may be formed through processes such as thermal deposition, vapor deposition, vacuum deposition, spin coating, inkjet printing, laser printing, casting, and/or laser thermal transfer. For example, selective deposition of the emission layer EML for each pixel may be effectively performed by the pixel defining film PDL having the step structure.

In one or more embodiments, a hole injecting layer may be further formed between the pixel electrode 180 and the hole transporting layer HTL. An electron injecting layer may be further formed between a counter electrode 190 and the electron transporting layer ETL.

The counter electrode 190 may be disposed on the pixel defining layer PDL and the emission layer EML. The counter electrode 190 may be formed on the electron transporting layer ETL.

The counter electrode 190 may be a common electrode commonly and continuously provided to a plurality of emission areas or pixels.

The counter electrode 190 may be provided as an electron injecting electrode or a cathode. The counter electrode 190 may include a metal, an alloy, an electrically conductive compound, and/or the like, having a low work function.

For example, the counter electrode 190 may include lithium (Li), silver (Ag), magnesium (Mg), aluminum (Al), aluminum-lithium (Al-Li), calcium (Ca), magnesium-indium (Mg- In), magnesium-silver (Mg-Ag), ytterbium (Yb), silver-ytterbium (Ag-Yb), ITO, IZO, and/or the like. These materials may be utilized alone or in a combination of two or more.

The counter electrode 190 may be provided as a transmissive electrode, a semi-transmissive electrode, and/or a reflective electrode. The counter electrode 190 may have a single-layer structure or a multilayer structure.

The light-emitting element LE may be defined by a stacked structure of the pixel electrode 180, the hole transporting layer HTL, the emission layer EML, the electron transporting layer ETL, and the counter electrode 190 described above. For example, the light-emitting element LE may be electrically connected to the transistor of each pixel through the drain electrode DE.

The light-emitting element LE may include the first light-emitting element LE1, the second light-emitting element LE2, and the third light-emitting element LE3 that respectively include the first emission layer EML1, the second emission layer EML2, and the third emission layer EML3. In one or more embodiments, the first light-emitting element LE1, the second light-emitting element LE2, and the third light-emitting element LE3 may be provided as a red light-emitting element, a green light-emitting element, and a blue light-emitting element, respectively.

The encapsulation layer TFE covering the light-emitting elements LE1, LE2, and LE3 may be disposed on the counter electrode 190. The encapsulation layer TFE may be disposed on the pixel defining layer PDL and the light-emitting elements LE1, LE2, and LE3 to protect the light-emitting elements LE1, LE2, and LE3 from moisture or oxygen.

The encapsulation layer TFE may include an inorganic film including silicon nitride (e.g., SiNₓ), silicon oxide (e.g., SiOₓ), indium tin oxide, indium zinc oxide, and/or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate, polyacrylic acid, etc.), an epoxy resin (e.g., aliphatic glycidyl ether (AGE), etc.), and/or a combination thereof; and/or a combination of the inorganic film and the organic film.

The encapsulation layer TFE may be formed in a single-layer or multilayer structure. In one or more embodiments, the encapsulation layer TFE may have a structure in which a first inorganic layer, an organic layer, and a second inorganic layer are sequentially stacked.

A base layer 200, the bank BK formed on the base layer 200, and the light controllers CR, CG, and CB defined by the bank BK may be formed on the encapsulation layer TFE.

The base layer 200 may be provided as a base for the bank BK and the light controllers CR, CG, and CB, and may include the above-described inorganic insulating material.

As described with reference to FIG. 2, the third light controller CB may be provided as a phase difference layer 220 and a polarizing plate (e.g., a quarter wave plate 230 and a linear polarizing plate 240), and the first light controller CR and the second light controller CG may be provided as a red coloring layer and a green coloring layer, respectively. The first light controller CR, the second light controller CG, and the third light controller CB may overlap the first light-emitting element LE1, the second light-emitting element LE2, and the third light-emitting element LE3, respectively, in the third direction.

A protective layer 250 covering the bank BK and the light controllers CR, CG, and CB may be formed on the bank BK and the light controllers CR, CG, and CB. The protective layer 250 may include the above-described inorganic insulating material and/or an organic insulating material.

According to one or more embodiments, the third light controller CB may include the phase difference layer 220 and the polarizing plate disposed on the phase difference layer. The polarizing plate may include the linear polarizing plate 240 disposed on the quarter wave plate 230.

According to one or more embodiments, the phase difference layer 220 of the third light controller CB disposed on the blue light-emitting element LE3 may be a blue cholesteric liquid crystal layer.

According to one or more embodiments, the first light controller CR and the second light controller CG may be provided as color filters. The first light controller CR and the second light controller CG may be provided as a red color filter and a green color filter, respectively.

According to one or more embodiments, the first and second light controllers CR and CG may not include a polarizing plate.

The first light controller CR and the second light controller CG, which may be the color filters, may be respectively disposed above the red light-emitting element LE1 and the green light-emitting element LE2 each having a single emission layer, and the third light controller CB including the phase difference layer 220 and the polarizing plates 230 and 240 may be disposed above the blue light-emitting element LE3 having a tandem structure.

FIG. 4 is a schematic cross-sectional view illustrating a light-emitting element of the display device according to one or more embodiments.

Referring to FIG. 4, the light-emitting element LE of the display device described with reference to FIG. 3 may have a tandem structure. In embodiments, the third light-emitting element LE3 may have a tandem structure.

As illustrated in FIG. 4, the light-emitting element LE3 may include a light emitter EL3 disposed between the pixel electrode 180 and the counter electrode 190. The hole transporting layer HTL, the emission layer EML3, and the electron transporting layer ETL of FIG. 3 may correspond to the light emitter EL3 of FIG. 4.

The light emitter EL3 may include a plurality of emission structures. Each of the emission structures may include a hole transporting layer, an emission layer, and/or an electron transporting layer.

In one or more embodiments, the emission structures may include a first emission structure ES1, a second emission structure ES2, and/or a third emission structure ES3.

A charge generation layer may be disposed between the emission structures. The charge generation layer may include a p-type (kind) charge generation layer and/or an n-type (kind) charge generation layer. For example, the charge generation layer may include a first charge generation layer CGL1 disposed between the first emission structure ES1 and the second emission structure ES2 and a second charge generation layer CGL2 disposed between the second emission structure ES2 and the third emission structure ES3.

According to one or more embodiments, the first emission structure ES1, the first charge generation layer CGL1, the second emission structure ES2, the second charge generation layer CGL2, the third emission structure ES3, and the counter electrode 190 may be sequentially stacked on the upper surface of the pixel electrode 180.

The light-emitting element LE having a three-layer tandem structure may be illustrated in FIG. 4, but the light-emitting element LE may also have a two-layer or four-layer or more tandem structure.

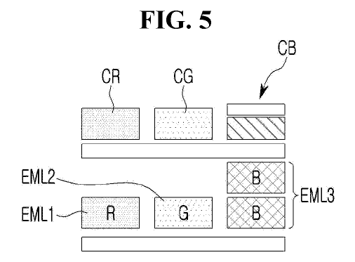

FIG. 5 is a schematic cross-sectional view of the display device according to one or more embodiments. FIG. 5 illustrates only the emission layer and the light controller of the display device of FIG. 3.

Referring to FIG. 5, the first light controller CR may be formed on the first light-emitting element including the first emission layer EML1, the second light controller CG may be formed on the second light-emitting element including the second emission layer EML2, and the third light controller CB may be formed on the third light-emitting element including the third emission layer EML3.

According to one or more embodiments, the first emission layer EML1 may be a red emission layer, the second emission layer EML2 may be a green emission layer, and the third emission layer EML3 may be a blue emission layer.

The third light-emitting element may have the tandem structure in which the plurality of emission layers are stacked as described above with reference to FIG. 4. It may be illustrated in FIG. 5 that the third light-emitting element may have two third emission layers, but the scope of the present disclosure may be not limited thereto, and the number of emission layers included in the tandem structure may be appropriately selected.

The first light controller CR and the second light controller CG may be color filters. The first light controller CR may be a red coloring layer, and the second light controller CG may be a green coloring layer.

The third light controller CB may include the phase difference layer 220 and the polarizing plates 230 and 240 as described above in FIGS. 2 and 3.

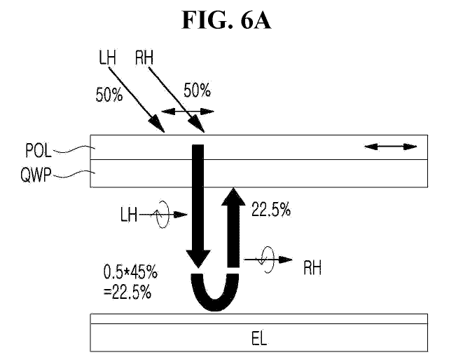

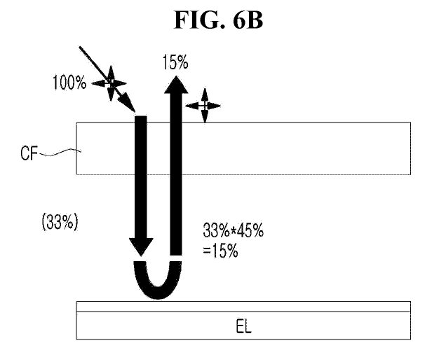

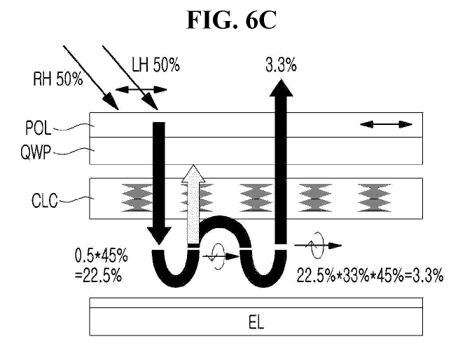

FIGS. 6A to 6C are views for describing amount of reflection of external light of display devices according to one or more embodiments. FIGS. 6A and 6B illustrate comparative examples, and FIG. 6C illustrates an example embodiment. It is assumed in FIGS. 6A, 6B, and 6C that the light-emitting element may be a blue light-emitting element.

FIG. 6A illustrates a case where a light controller may include a quarter wave plate QWP and a linear polarizing plate POL disposed on the quarter wave plate QWP. For example, an optical axis of the quarter wave plate QWP deviates from a polarization axis of the linear polarizing plate POL by approximately 45°.

External light (in an unpolarized state) may be linearly polarized in a polarization axis direction (denoted by ↔) of the linear polarizing plate POL while passing through the linear polarizing plate POL. The linearly polarized light may change into circularly polarized light while passing through the quarter wave plate QWP.

Because an angle between an axis direction of the linearly polarized light as described above and an optical axis direction of the quarter wave plate QWP may be approximately 45°, the linearly polarized light may change into the circularly polarized light while passing through the quarter wave plate QWP. The circularly polarized light in this embodiment may be assumed to be left-handed circularly polarized light.

The external light may be in an unpolarized state, and thus, may include left-handed circularly polarized light and right-handed circularly polarized light. Only the left-handed circularly polarized light of the external light passes through the quarter wave plate, and thus, approximately 50% of the external light passes through the quarter wave plate.

The left-handed circularly polarized light may be reflected on an electrode, for example, the counter electrode of FIG. 3, of the light-emitting element. Assuming that a reflectivity in this case may be approximately 45%, approximately 22.5% of the external light may be reflected by the light-emitting element.

Because a polarization direction may change during reflection, the light reflected by the light-emitting element may become right-handed circularly polarized light. Because the right-handed circularly polarized light may not be transmitted through the linear polarizing plate POL, the polarizing plate of FIG. 6a may have an external light reflectivity of approximately 0%.

The polarizing plate of FIG. 6A may have an excellent external light reflectivity as described above, but also blocks light emitted from the light-emitting element to the outside, and thus, luminance may be reduced.

FIG. 6B illustrates a case where a light controller may be a color filter CF. The color filter CF may be assumed to be a blue color filter.

The color filter may be to transmit only light of a corresponding color among external light. For example, when the color filter may be a blue color filter, the color filter may be to transmit only blue light of red light, green light, and/or blue light. Accordingly, about 33% of the external light may be transmitted through the color filter.

The light transmitted through the color filter (about 33% of the external light) may be reflected by the electrode of the light-emitting element. Assuming that a reflectivity of the electrode of the light-emitting element of approximately 45%, approximately 45% of 33% of the external light, for example, 15% of the external light, may be reflected by the light-emitting element.

The reflected light may be blue light, and thus, may entirely pass through the blue color filter.

Accordingly, the color filter CF of FIG. 6B may have an external light reflectivity of approximately 15%.

A case where the color filter CF may be the blue color filter may have been described by way of example, but a red color filter or a green color filter may also have substantially the same external light reflectivity.

FIG. 6c illustrates a case where a light controller may include a cholesteric liquid crystal layer CLC, a quarter wave plate QWP, and a linear polarizing plate POL. Similar to FIG. 6A, an optical axis of the quarter wave plate QWP may deviate from a polarization axis of the linear polarizing plate POL by approximately 45°.

Referring to FIG. 6C, external light (in an unpolarized state) may be linearly polarized in a polarization axis direction (denoted by ↔) of the linear polarizing plate POL while passing through the linear polarizing plate POL. The linearly polarized light may change into circularly polarized light while being transmitted through the quarter wave plate QWP. The circularly polarized light in this embodiment may be assumed to be left-handed circularly polarized light. However, the present disclosure may be not limited thereto, and the quarter wave plate QWP may also be disposed so that light transmitted through the quarter wave plate QWP may be right-handed circularly polarized light.

As described above with reference to FIG. 6A, only left-handed circularly polarized light among the external light may be transmitted through the quarter wave plate QWP, and thus, approximately 50% of the external light may be transmitted through the quarter wave plate QWP.

Assuming that the cholesteric liquid crystal layer CLC may transmit the left-handed circularly polarized light, the light passing through the quarter wave plate QWP may be entirely transmitted through the cholesteric liquid crystal layer CLC and then reflected on the electrode of the light-emitting element. Assuming that a reflectivity in this case may be approximately 45%, 22.5% of the external light may be reflected by the light-emitting element.

The reflected light becomes right-handed circularly polarized light due to a change in polarization direction, and may be reflected by the cholesteric liquid crystal layer CLC. Assuming that the cholesteric liquid crystal layer CLC may be a blue cholesteric liquid crystal layer, only blue light among light incident on the cholesteric liquid crystal layer CLC may be reflected, such that approximately 7.5%, which may be approximately 33% of 22.5% of the external light, may be reflected.

The light reflected by the cholesteric liquid crystal layer CLC may be re-reflected on the electrode of the light-emitting element. Accordingly, the right-handed circularly polarized light may change into left-handed circularly polarized light. Approximately 3.3%, which may be 45% of 7.5% of the external light may be reflected by the light-emitting element.

The left-handed circularly polarized light sequentially passes through the cholesteric liquid crystal layer CLC, the quarter wave plate QWP, and the linear polarizing plate POL, as described above, and may be then emitted to the outside.

Accordingly, the light controller of FIG. 6C may have an external light reflectivity of approximately 3.3%.

As described above, the light controller of FIG. 6C according to one or more embodiments may have a low external light reflectivity, and may have high luminance because it may emit the light emitted from the light-emitting element to the outside.

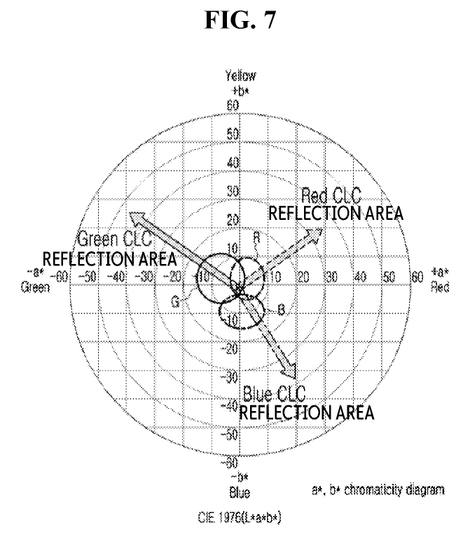

FIG. 7 is a diagram for describing an aspect of color sense adjustment according to one or more embodiments.

FIG. 7 illustrates a* anId b* of three axes oIf L*, a*, and b* in the CIE color coordinates. In one or more embodiments, a red color may become deeper toward a +a* direction, a green color becomes deeper toward a -a* direction, a yellow color becomes deeper toward a +b* direction, and a blue color becomes deeper toward a -b* direction.

The display device in which the blue light-emitting element LE3 may have the tandem structure and the red light-emitting element LE1 and the green light-emitting element LE2 each may include the single emission layer as illustrated in FIGS. 3 and 5 may exhibit a bluish color sense. As illustrated in FIG. 7, as an amount of reflected blue light may increase, an absolute value of -b* may increase. Accordingly, to reduce the bluish color sense of the display device and for the display device to have a reddish color sense, it may be suitable to reduce amount of reflection of a blue external light.

Referring to FIG. 7, to reduce the absolute value of -b*, for example, to increase a value of b*, considering a conversion relationship between a* and b* in the XYZ color coordinates and the Lab color coordinates, a Z value indicating the blue color may be reduced and/or a Y value indicating the green color may be increased.

According to one or more embodiments, the third light controller CB disposed on the blue light-emitting element LE3 may include the phase difference layer and the polarizing plate, and may thus reduce amount of reflection of the blue external light. Accordingly, it may be possible to reduce the Z value, such that it may be possible to improve a color sense.

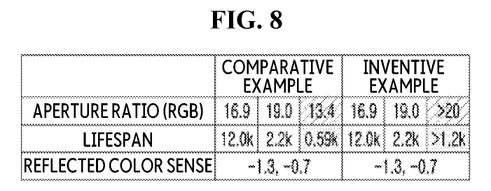

FIG. 8 is a comparison table for describing aspects of an aperture ratio increase and a lifespan increase according to one or more embodiments.

In a display device according to a comparative example, a red color filter was provided as a first light controller on a red light-emitting element, a green color filter was provided as a second light controller on a green light-emitting element, and a blue color filter was provided as a third light controller on a blue light-emitting element having a tandem structure. An example embodiment may be different from a comparative example in that the third light controller may be provided as the phase difference layer 220 and the polarizing plates 230 and 240, as described above with reference to FIGS. 3 and 5.

As illustrated in FIG. 8, to improve a bluish color sense, an aperture ratio of the blue light-emitting element may be made to be smaller than those of the red light-emitting element and the green light-emitting element in a comparative example, but it was possible to make an aperture ratio of the blue light-emitting element greater than those of the red light-emitting element and the green light-emitting element in an example embodiment.

When an aperture ratio may be high, light of the same brightness may be emitted even with less power consumption, and thus, energy efficiency may be high. Accordingly, power may be less consumed, such that a lifespan of the display device may be increased. An aspect of a lifespan increase due to an aperture ratio increase was confirmed from FIG. 8.

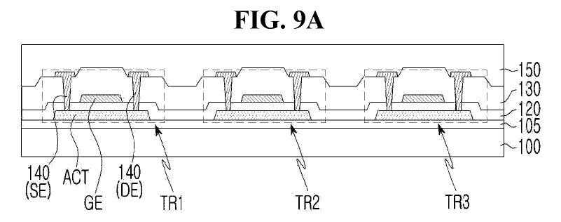

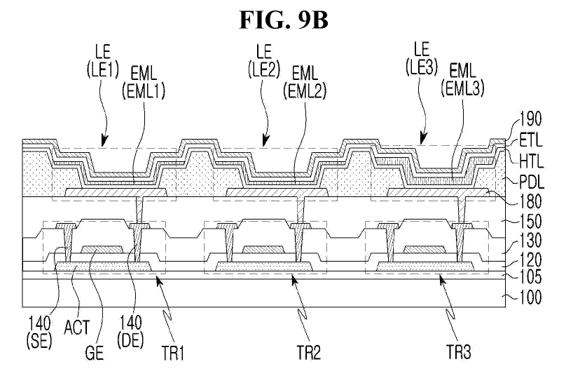

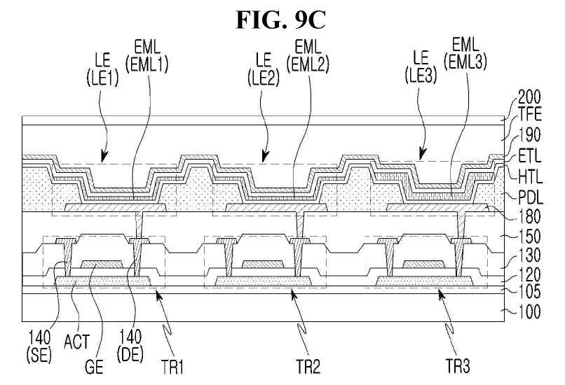

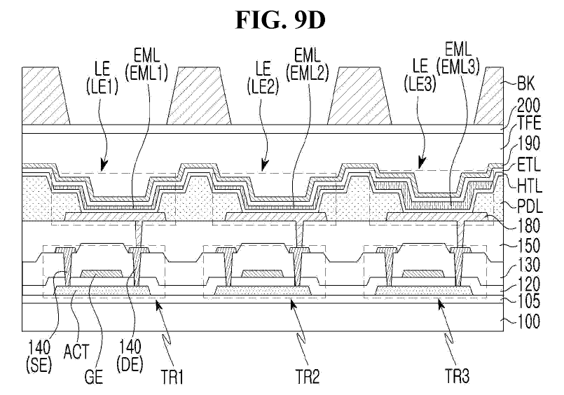

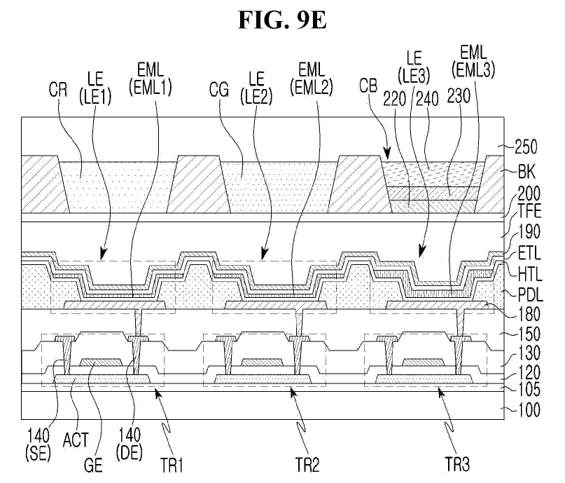

FIGS. 9A-9E are cross-sectional views illustrating a manufacturing method of the display device according to one or more embodiments.

Referring to FIG. 9A, a pixel circuit in which the planarization layer 150 may be formed on the transistors TR1, TR2, and TR3.

Referring to FIG. 9B, the pixel electrodes 180 may be formed on the planarization layer 150, and the light-emitting elements LE1, LE2, and LE3 may be formed on the pixel electrodes 180, respectively. As described above with reference to FIG. 3, the light-emitting elements LE1 and LE2 may include the single emission layers EML1 and EML2, respectively, and the light-emitting element LE3 may have the tandem structure including the plurality of emission layers. In each of the light-emitting elements LE1, LE2, and LE3, the hole transporting layer HTL adjacent to the pixel electrode 180, the electron transporting layer ETL adjacent to the counter electrode 190, and the counter electrode 190 may be continuously formed.

Referring to FIG. 9C, the encapsulation layer TFE covering the light-emitting elements LE1, LE2, and LE3 may be formed, and the base layer 200 may be formed on the encapsulation layer TFE.

Referring to FIG. 9D, the bank BK in which the openings may be formed may be formed on the respective light-emitting elements LE1, LE2, and LE3. According to one or more embodiments, a size of an opening formed on the light-emitting element LE3 having the tandem structure may be greater than a size of openings formed on the light-emitting element LE1 and LE2 each having the single emission layer.

Referring to FIG. 9E, the light controllers CR, CG, and CB may be located in the respective openings. According to one or more embodiments, the first and second light controllers CR and CG disposed on the light-emitting elements LE1 and LE2 each including the single emission layer may be color filters. The third light controller CB disposed on the light-emitting element LE3 having the tandem structure may include the phase difference layer 220 and the polarizing plates 230 and 240.

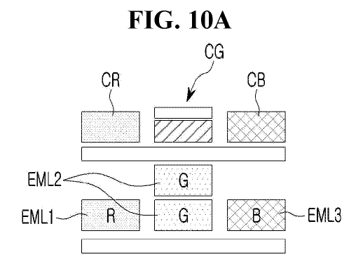

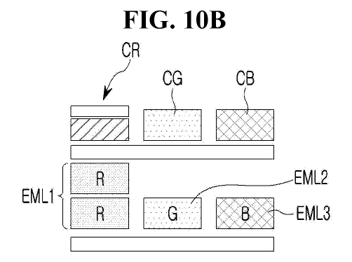

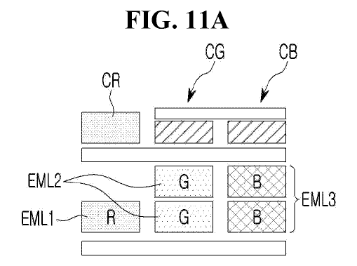

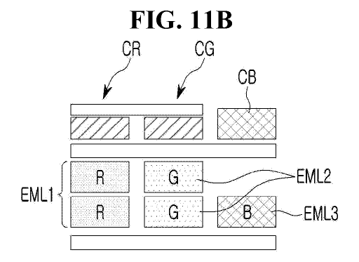

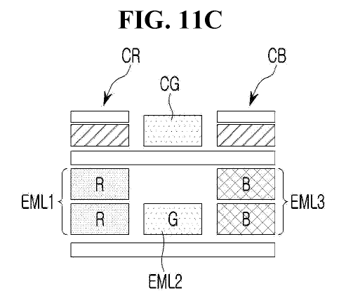

FIGS. 10A, 10B, and 11A-11C are schematic cross-sectional views of display devices according to one or more embodiments.

Referring to FIG. 10A, in a display device according to one or more embodiments, a second light-emitting element, which may be a green light-emitting element, may have a tandem structure including a plurality of emission layers, and a second light controller CG including a green cholesteric liquid crystal layer and a polarizing plate may be disposed on the second light-emitting element. A first light-emitting element, which may be a red light-emitting element, and a third light-emitting element, which may be a blue light-emitting element, may each include a single emission layer, and a first light controller CR of a red coloring layer and a third light controller CB of a blue coloring layer may be disposed on the first light-emitting element and the third light-emitting element, respectively.

Referring to FIG. 10B, in a display device according to one or more embodiments, a first light-emitting element, which may be a red light-emitting element, may have a tandem structure including a plurality of emission layers, and a first light controller CR including a red cholesteric liquid crystal layer and a polarizing plate may be disposed on the first light-emitting element. A second light-emitting element, which may be a green light-emitting element, and a third light-emitting element, which may be a blue light-emitting element, may each include a single emission layer, and a second light controller CG of a green coloring layer and a third light controller CB of a blue coloring layer may be disposed on the second light-emitting element and the third light-emitting element, respectively.

The display devices of FIGS. 10A and 10B may be similar to the display device of FIG. 5 in that one light-emitting element may have the tandem structure in which the plurality of emission layers may be stacked and the light controller including the cholesteric liquid crystal layer and the polarizing plate may be provided on one light-emitting element.

Referring to FIG. 11A, in a display device according to one or more embodiments, each of a second light-emitting element, which may be a green light-emitting element, and a third light-emitting element, which may be a blue light-emitting element, may have a tandem structure. A second light controller CG including a green cholesteric liquid crystal layer and a polarizing plate and a third light controller CB including a blue cholesteric liquid crystal layer and a polarizing plate may be disposed on the second light-emitting element and the third light-emitting element, respectively. A first light-emitting element, which may be a red light-emitting element, may include a single emission layer, and a first light controller CR of a red coloring layer may be disposed on the first light-emitting element.

With the display device of FIG. 11A, an aspect of reducing the absolute value of -b* by reducing blue external light reflection may be obtained.

Referring to FIG. 11B, in a display device according to one or more embodiments, each of a first light-emitting element, which may be a red light-emitting element, and a second light-emitting element, which may be a green light-emitting element, may have a tandem structure. A first light controller CR including a red cholesteric liquid crystal layer and a polarizing plate and a second light controller CG including a green cholesteric liquid crystal layer and a polarizing plate may be disposed on the first light-emitting element and the second light-emitting element, respectively. A third light-emitting element, which may be a blue light-emitting element, may include a single emission layer, and a third light controller CB of a blue coloring layer may be disposed on the third light-emitting element.

With the display device of FIG. 11B, luminance of green light may increase.

Referring to FIG. 11C, in a display device according to one or more embodiments, each of a first light-emitting element, which may be a red light-emitting element, and a third light-emitting element, which may be a blue light-emitting element, may have a tandem structure. A first light controller CR including a red cholesteric liquid crystal layer and a polarizing plate and a third light controller CB including a blue cholesteric liquid crystal layer and a polarizing plate may be disposed on the first light-emitting element and the third light-emitting element, respectively. A second light-emitting element, which may be a green light-emitting element, may include a single emission layer, and a second light controller CG of a green coloring layer may be disposed on the second light-emitting element.

As illustrated in FIGS. 11A-11C, when the polarizing plate may be provided for a plurality of light-emitting elements, the polarizing plate may be provided continuously for the plurality of light-emitting elements.

It may be illustrated in FIGS. 10A, 10B, and 11A-11C that the light-emitting element having the tandem structure may have two emission layers, but the scope of the present disclosure may be not limited thereto, and the number of emission layers may be two or more.

It may be illustrated in FIGS. 11A-11C that the light-emitting elements each having the tandem structure have the same or substantially the same number of emission layers, but the numbers of emission layers included in the light-emitting elements may be different from each other.

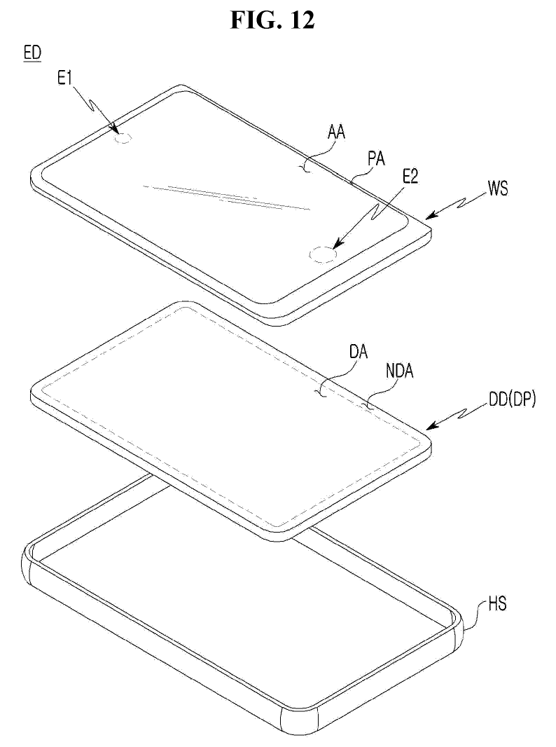

FIG. 12 is an exploded perspective view illustrating an electronic device according to one or more embodiments.

According to one or more embodiments, an electronic device ED may be implemented in the form of a mobile phone (smartphone), a tablet personal computer (PC), a PC, and/or the like, including the above-described display device.

Referring to FIG. 12, the electronic device ED may include a window structure WS, a display device DD, and a housing HS. The display device DD may include a display panel DP including the above-described transistor elements and light-emitting element LE. The housing HS, the display device DD, and the window structure WS may be sequentially stacked along the third direction.

The window structure WS may provide an external display surface recognized by a user, such as a viewing surface of the electronic device such as a mobile phone, and may include a transparent material film. For example, the window structure WS may include a glass (e.g., ultra-thin glass (UTG)), a hard coating film, a plastic film, and/or the like.

An outer surface of the window structure WS may include an active area AA and a peripheral area PA. The active area AA may provide a surface on which an image of the display device DD may be substantially displayed and to which a user’s touch/command may be input. The peripheral area PA may substantially correspond to a bezel area of the electronic device ED.

The display device DD or the display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In one or more embodiments, functional element areas E1 and E2 may be included in the active area AA of the window structure WS. For example, a first functional element area E1 may be included in one end of the active area AA, and may be implemented in the form of, for example, a camera hole. A second functional element area E2 may be provided as a fingerprint sensing area.

For example, a sensor structure for touch sensing or fingerprint sensing may be disposed in the display panel DP or between the window structure WS and the display panel DP.

The housing HS may be provided as a chassis structure or a rear housing of the display device DD or the electronic device ED. A cover panel may be disposed between the housing HS and the display panel DP. The housing HS or the cover panel may include a plate (e.g., a stainless-steel plate) supporting the display panel DP, the printed circuit board 300 (see FIG. 1), or the like. The housing HS or the cover panel may include an elastic body for absorbing a shock of the display device DD.

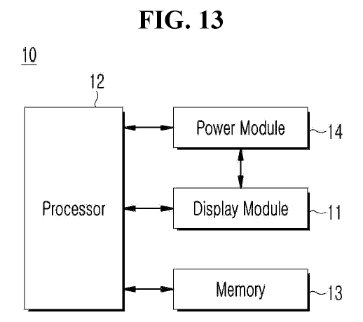

FIG. 13 is a block diagram of an electronic device according to one or more embodiments.

Referring to FIG. 13, an electronic device 10 according to one or more embodiments may include a display 11, a processor 12, a memory 13, and a power supply 14.

The processor 12 may include a central processing unit (CPU), an application processor (AP), a graphic processing unit (GPU), a communication processor (CP), an image signal processor (ISP), and/or a controller.

The memory 13 may store data information suitable for an operation of the processor 12 or the display 11. When the processor 12 executes an application stored in the memory 13, an image data signal and/or an input control signal may be transmitted to the display 11, and the display 11 may process the received signal and output image information through a display screen.

The power supply 14 may include a power supply device such as a power adapter or a battery device and a power conversion device converting power supplied by the power supply device to generate power suitable for an operation of the electronic device 10.

At least one of the respective components of the above-described electronic device 10 may be included in the display device according to the above-described embodiments. In addition, some of individual devices functionally included in one device may be included in the display device, and the others of the individual devices may be provided separately from the display device. For example, the display 11 may include the display device, and the processor 12, the memory 13, and the power supply 14 may be provided in the form of other devices within the electronic device 10 rather than the display device.

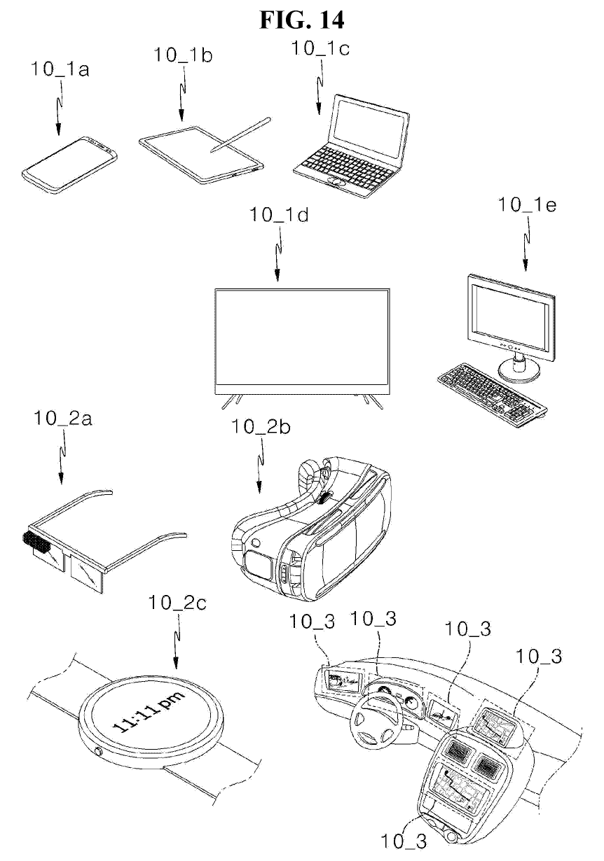

FIG. 14 is schematic views of electronic devices according to one or more embodiments.

Referring to FIG. 14, nonrestrictive examples of suitable electronic devices to which the display devices according to the above-described embodiments may be applied may include not only image display electronic devices such as a smartphone 10_1a, a tablet PC 10_1b, a laptop computer 10_1c, a television (TV) 10_1d, and a monitor 10_1e for a desktop computer; wearable electronic devices including display devices, such as smart glasses 10_2a, a head mounted display 10_2b, and a smart watch 10_2c; and vehicle electronic devices 10_3 including display devices, such as a center information display (CID) disposed on an instrument board, a center fascia, or a dashboard of a vehicle and a room mirror display. The electronic device may include virtual reality (VR) glasses or augmented reality (AR) glasses.

For example, at least some of light-emitting elements may have a tandem structure (e.g., a light-emitting element may include a light emitter disposed between layers of the tandem structure), and a phase difference layer and a polarizing plate may be above the light-emitting elements having the tandem structure. Such stacked structure of the light emitting controller may recycle the reflected light to improve luminance. Furthermore, the transmission axis of the polarizing plate may be aligned with the transmitted light to improve transmissivity. Accordingly, optical/color characteristics may be effectively implemented, and a lifespan of the light-emitting elements having the tandem structure may be improved.

As used herein, the terms "substantially," "about," and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

In the context of the present disclosure and unless otherwise defined, the terms "use," "using," and "used" may be considered synonymous with the terms "utilize," "utilizing," and "utilized," respectively.

Any numerical range recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display apparatus, a device of manufacturing a display apparatus, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the one or more suitable components of the device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the present disclosure.

In concluding the detailed description, those skilled in the art will appreciate that one or more suitable modifications may be made to one or more embodiments without substantially departing from aspects of embodiments of the present disclosure. Therefore, one or more embodiments of the present disclosure may be utilized in a generic and descriptive sense only and not for purposes of limitation.

What is claimed is:

1. A display device comprising:
light-emitting elements that emit light of different colors and comprising a first light-emitting element having a tandem structure and a second light-emitting element comprising a second emission layer, wherein the tandem structure of the first light-emitting element comprises a plurality of first emission layers that are stacked;
a first light controller above the first light-emitting element and comprising a first phase difference layer and a polarizing plate above the first phase difference layer; and
a second light controller above the second light-emitting element and comprising a first coloring layer.

2. The display device of claim 1, wherein the first phase difference layer is a cholesteric liquid crystal layer of an emission color of the first light-emitting element.

3. The display device of claim 1, wherein the polarizing plate comprises a linear polarizing plate above a quarter wave plate.

4. The display device of claim 1, wherein the first light-emitting element is a blue light-emitting element.

5. The display device of claim 4, wherein an aperture ratio of the first light-emitting element is greater than an aperture ratio of the second light-emitting element.

6. The display device of claim 4, wherein the display device has a b* value of -1.0 or more in Lab color coordinates.

7. The display device of claim 1, further comprising:
a third light-emitting element that emits light of a different color from the first and second light-emitting elements and having a tandem structure, wherein the tandem structure of the third light-emitting element comprises a plurality of third emission layers that are stacked; and
a third light controller above the third light-emitting element and comprising a second phase difference layer and the polarizing plate.

8. The display device of claim 7, wherein a number of third emission layers is the same as a number of first emission layers.

9. The display device of claim 7, wherein the second phase difference layer is a cholesteric liquid crystal layer of an emission color of the third light-emitting element.

10. The display device of claim 7, wherein the first light-emitting element is a blue light-emitting element, and the third light-emitting element is a green light-emitting element.

11. The display device of claim 1, further comprising:
a third light-emitting element emitting light of a different color from the first and second light-emitting elements and comprising one third emission layer; and
a third light controller above the third light-emitting element and comprising a second coloring layer.

12. The display device of claim 1, wherein the first light-emitting element has emission structures, wherein respective emission structure comprises a corresponding first emission layer, and the emission structures are stacked with a charge generation layer, wherein the charge generation layer is between the emission structures.

13. A method comprising:
forming a first light emitter comprising first emission layers;
forming a second light emitter comprising a second emission layer;
forming a first light controller above the first light emitter, the first light controller comprising a first phase difference layer and a polarizing plate above the first phase difference layer; and
forming a second light controller on the second light emitter, the second light controller comprising a first coloring layer,
wherein the method is a method for manufacturing a display device.

14. The method of claim 13, wherein the first light emitter is formed above a first pixel electrode, and the second light emitter is formed above a second pixel electrode.

15. The method of claim 14, further comprising:
forming an electrode on the first light emitter and the second light emitter; and
forming a bank on the electrode, the bank defining a first opening on the first light emitter and a second opening on the second light emitter.

16. The method of claim 15, wherein the first light controller is formed at the first opening, and the second light controller is formed at the second opening.

17. The method of claim 15, wherein a size of the first opening is greater than a size of the second opening.

18. The method of claim 13, further comprising:
forming a third light emitter comprising third emission layers; and
forming a third phase difference layer on the third light emitter, and
wherein the forming of the first light controller comprises forming the first phase difference layer above the first light emitter, and forming the polarizing plate covering the first phase difference layer and the third phase difference layer.

19. An electronic device comprising:
a display device;
a memory; and
a processor that controls an operation of the display device by executing data stored in the memory,
wherein the display device comprises:
light-emitting elements that emit light of different colors and comprising a first light-emitting element having a tandem structure and a second light-emitting element comprising one second emission layer, wherein the tandem structure comprises a plurality of first emission layers that are stacked;
a first light controller above the first light-emitting element and comprising a first phase difference layer and a polarizing plate above the first phase difference layer; and
a second light controller above the second light-emitting element and comprising a first coloring layer.

20. The electronic device of claim 19, wherein the electronic device comprises virtual reality (VR) or augmented reality (AR) glasses, a smartphone, a tablet personal computer (PC), a laptop computer, a television (TV), a monitor for a desktop computer, smart glasses, a head mounted display, a smart watch, or a vehicle display.
